(19) United States
(12) Patent Application Publication
(10) Pub. No.: US 2024/0290769 A1
(43) Pub. Date: Aug. 29, 2024

(54) SEMICONDUCTOR DEVICE AND DISPLAY DRIVER INCLUDING THE SAME

(71) Applicant: LX SEMICON CO., LTD., Daejeon (KR)

(72) Inventors: Cheong Sik YU, Daejeon (KR); Kee Joon CHOI, Daejeon (KR)

(73) Assignee: LX SEMICON CO., LTD., Daejeon (KR)

(21) Appl. No.: 18/584,467

(22) Filed: Feb. 22, 2024

(30) Foreign Application Priority Data
Feb. 23, 2023 (KR) 10-2023-0024084

(51) Int. Cl. H01L 25/18; H01L 23/00; H01L 23/528

(52) U.S. Cl. CPC H01L 25/18; H01L 23/5283; H01L 24/05; H01L 24/06; H01L 24/08; H01L 24/13; H01L 2224/05567; H01L 2224/0557; H01L 2224/05644; H01L 2224/05647; H01L 2224/06181; H01L 2224/08145; H01L 2224/13021; H01L 2224/13144; H01L 2224/13147; H01L 2924/1426

(57) ABSTRACT

Disclosed is a semiconductor device including a low voltage device located on a first substrate and driven with a first level voltage, and a high voltage device located on a second substrate, driven with a second level voltage higher than the first level voltage, and coupled to the low voltage device, wherein the low voltage device includes a FinFET, wherein the high voltage device includes a planar FET.

This application claims the benefits Korean Patent Application No. 10-2023-0024084, filed on Feb. 23, 2023, which is hereby incorporated by reference in its entirety as if fully set forth herein.

### BACKGROUND

### Field

The present disclosure relates to a semiconductor device and a display driver including the same.

### Discussion of the Related Art

As an information society develops, demands for a display device to display an image are increasing in various forms. Accordingly, recently, various types of display devices such as a liquid crystal display device (LCD) and an organic light emitting display device (OLED) have been used.

The display device includes a display panel and a display driver. The display panel is composed of a number of pixels arranged in a matrix, and each pixel is composed of R (red), G (green), B (blue), and the like sub-pixels. Further, as each pixel or each sub-pixel emits light in a grayscale based on the image, the image is displayed on an entire display panel.

Image data (display data) indicating a grayscale value of each pixel or each sub-pixel is transferred to the display panel via the display driver. Such display driver may be constructed as a semiconductor device that include a circuit for generating the image data. Recently, the semiconductor device for reducing a size of display driver and reducing power consumption has been developed.

### SUMMARY

The present disclosure is to provide a semiconductor device and a display driver including the same that may reduce power consumption and reduce an area size.

A semiconductor device according to one embodiment of the present disclosure includes a low voltage device located on a first substrate and driven with a first level voltage, and a high voltage device located on a second substrate, driven with a second level voltage higher than the first level voltage, and coupled to the low voltage device, the low voltage device includes a FinFET, and the high voltage device includes a planar FET.

The semiconductor device and the display driver including the same according to one embodiment of the present disclosure may reduce the area size of the semiconductor device and reduce the power consumption.

Additionally, the semiconductor device and the display driver including the same according to one embodiment of the present disclosure may reduce the manufacturing cost of the semiconductor device and the display driver including the same.

### BRIEF DESCRIPTION OF THE DRAWINGS

FIG. 1 is a diagram showing a display device to which a display driver according to an embodiment of the present disclosure is applied.

FIG. 2 is a diagram showing each of circuits constituting a display driver according to an embodiment of the present disclosure.

FIG. 3 is a block diagram schematically showing a structure of a display driver according to an embodiment of the present disclosure.

FIG. 4 is a diagram showing first surfaces of first and second substrates on which respective circuits are formed by disassembling a display driver according to an embodiment of the present disclosure.

FIG. 5A is a schematic cross-sectional view of a display driver according to an embodiment of the present disclosure.

FIG. 5B is a schematic cross-sectional view of a display driver according to another embodiment of the present disclosure.

FIG. 6 is a perspective view of a first FEOL structure of a low voltage device according to an embodiment of the present disclosure.

FIG. 7 is a perspective view of a second FEOL structure of a high voltage device according to an embodiment of the present disclosure.

FIG. 8 is an enlarged view of a portion A in FIG. 5A.

### DESCRIPTION OF SPECIFIC EMBODIMENTS

Like reference numerals refer to substantially the same components throughout the present document. In the following description, when it is not related to the core components of the present disclosure, detailed descriptions of the components and the functions known in the technical field of the present disclosure may be omitted. The meaning of terms described herein should be understood as follows.

Advantages and features of the present disclosure, and a method of achieving the advantages and features will become apparent with reference to embodiments described later in detail together with the accompanying drawings. However, the present disclosure is not limited to the embodiments as disclosed below, but may be implemented in various different forms. Thus, these embodiments are set forth only to make the present disclosure complete, and to completely inform the scope of the present disclosure to those of ordinary skill in the technical field to which the present disclosure belongs, and the present disclosure is only defined by the scope of the claims.

A shape, a size, a ratio, an angle, a number, etc. disclosed in the drawings for describing embodiments of the present disclosure are illustrative, and the present disclosure is not limited thereto. The same reference numerals refer to the same elements herein. Additionally, when describing the present disclosure, when it is determined that a detailed description of the related known technology may unnecessarily obscure the gist of the present disclosure, the detailed description is omitted.

When ‘include’, ‘have’, ‘composed of’, and the like mentioned in herein are used, other components may be added unless ‘only’ is used. As used herein, the singular constitutes “a” and “an” are intended to include the plural constitutes as well, unless the context clearly indicates otherwise.

In interpreting a numerical value, the value is interpreted as including an error range unless there is no separate explicit description thereof.

In descriptions of temporal relationships, for example, temporal precedent relationships between two events such as “after”, “subsequent to”, “before”, etc., another event may occur therebetween unless “directly after”, “directly subsequent” or “directly before” is not indicated.

Although first, second, and the like are used to describe various components, such components are not limited by such terms. Such terms are merely used to distinguish one component from another. Accordingly, a first component mentioned below may be a second component within the technical idea of the present disclosure.

The term “at least one” should be understood to include all combinations that may be presented from one or more related items. For example, “at least one of first, second, and third items” may not only mean each of the first, second, and third items, but also combinations of all items that may be presented from two or more of the first, second, and third items.

The features of the various embodiments of the present disclosure may be partially or entirely combined with each other, and may be technically associated with each other or operate with each other. The embodiments may be implemented independently of each other and may be implemented together in an association relationship.

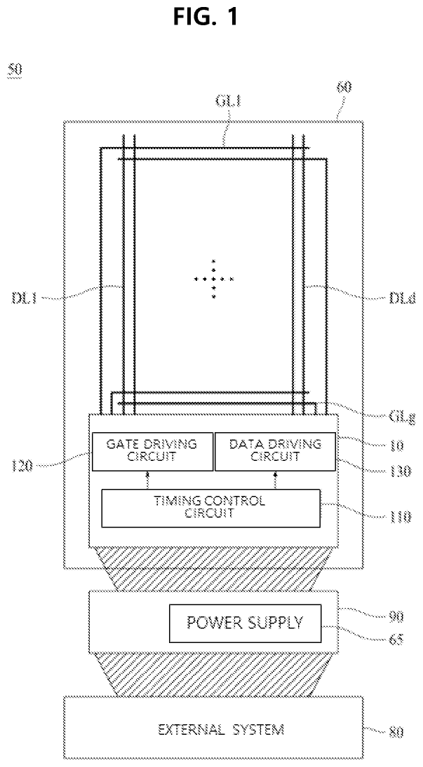

Hereinafter, a display device including a display driver according to an embodiment of the present disclosure will be described in detail with reference to FIG. 1. FIG. 1 is a diagram showing a display device to which a display driver according to an embodiment of the present disclosure is applied.

A display device 50 according to the present disclosure includes a display panel 60, a display driver 10, a power supply 65, and an external system 80.

The display panel 60 may be an organic light-emitting display panel on which organic light-emitting elements are formed or may be a liquid crystal panel on which liquid crystals are formed. In other words, as the display panel 60 applied to the present disclosure, all types of display panels currently in use may be applied. Therefore, the display device according to the present disclosure may also be an organic light-emitting display device, a liquid crystal display device, and various other types of display devices. However, hereinafter, for convenience of description, the liquid crystal display device will be described as an example of the present disclosure.

When the display panel 60 is the liquid crystal display panel, multiple data lines DL1 to DLd, multiple gate lines GL1 to GLg that intersect the data lines, multiple thin film transistors (TFTs) formed at intersections of the data lines and the gate lines, multiple pixel electrodes for charging a data voltage to pixels, and a common electrode for operating liquid crystals filled in a liquid crystal layer together with the pixel electrodes are formed on a lower glass substrate of the display panel 60, and pixels are arranged in a matrix form by the intersecting structure of the data lines and the gate lines.

A black matrix (BM) and a color filter are formed on an upper glass substrate of the display panel 60. The liquid crystals are filled between the lower glass substrate and the upper glass substrate.

A liquid crystal mode of the display panel 60 applied in the present disclosure may not only be a TN mode, a VA mode, an IPS mode, and an FFS mode, but also any type of liquid crystal mode. In addition, the display device 50 according to the present disclosure may be implemented in any form, such as a transmissive liquid crystal display device, a transflective liquid crystal display device, or a reflective liquid crystal display device.

The display panel 60 displays an image in response to a gate signal and a source signal output from the display driver 10.

The power supply 65 is mounted on a main board 90 and supplies a voltage to drive the display panel 60, the display driver 10, and the external system 80. In this regard, various circuit elements in addition to the power supply 65 may be mounted on the main board 90.

The power supply 65 generates the voltage based on a driving voltage of each circuit included in the display driver 10 and supplies the voltage to each circuit. In this regard, each circuit of the display driver 10 may be driven with a first level voltage or a second level voltage. In this regard, the first level voltage may be lower than the second level voltage. That is, the first level voltage may mean a low voltage and the second level voltage may mean a high voltage. For example, the first level voltage may be a voltage in a range from 1.1V to 2.0V, and the second level voltage may be a voltage equal to or higher than 7V.

Additionally, the power supply 65 supplies power for driving to the display panel 60.

The display driver 10 may be composed of a timing control circuit 110 for controlling a gate driving circuit 120 and a data driving circuit 130 formed on the display panel 60, the gate driving circuit 120 for controlling signals input to the gate lines, and the data driving circuit 130 for controlling signals input to the data lines formed on the display panel 60.

In this regard, it is shown in FIG. 1 that the display driver 10 is mounted on the display panel 60, but this is merely an example. The display driver 10 may be mounted via a separate board by being separated from the display panel 60.

In addition, the timing control circuit 110, the gate driving circuit 120, and the data driving circuit 130 that constitute the display driver 10 may be constructed as a single chip package as shown in FIG. 1, but may be constructed individually.

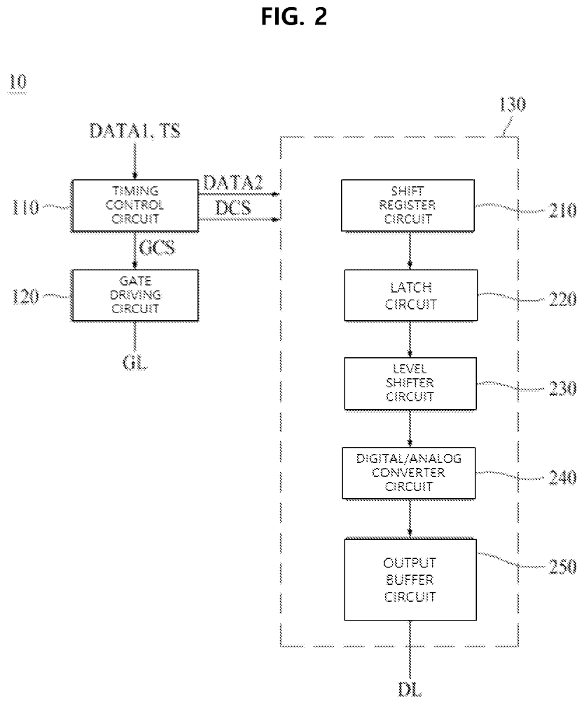

Hereinafter, the display driver according to one embodiment of the present disclosure will be described in detail with reference to FIG. 2. FIG. 2 is a diagram showing each of circuits constituting a display driver according to an embodiment of the present disclosure.

As shown in FIG. 2, the timing control circuit 110 controls the gate driving circuit 120 by supplying a gate control signal GCS to the gate driving circuit 120. Specifically, the timing control circuit 110 receives first image data DATA1 and timing signals TS from the external system 80. Based on a timing signal TS, the timing control circuit 110 generates the gate control signal GCS for controlling the gate driving circuit 120 and generates a data control signal DCS for controlling the data driving circuit 130.

In one embodiment, the timing control circuit 110 generates the gate control signal GCS including gate start pulse GSP, gate shift clock GSC, and gate output enable (GOE) signals.

In one embodiment, the timing control circuit 110 generates the data control signal DCS including source start pulse (SSP), source sampling clock (SSC), and source output enable (SOE) signals.

As shown in FIG. 2, the timing control circuit 110 transfers the gate control signal GCS to the gate driving circuit 120 and transfers the data control signal DCS to the data driving circuit 130.

The timing control circuit 110 sorts the first image data DATA1 received from the external system 80. Specifically, the timing control circuit 110 sorts the first image data DATA1 to match a structure and characteristics of the display panel 60 to generate second image data DATA2.

The timing control circuit 110 transfers the second image data DATA2 to the data driving circuit 130, as shown in FIG. 2.

The gate driving circuit 120 outputs the gate signal synchronized with the source signals generated by the data driving circuit 130 to the gate line in response to the timing signal generated by the timing control circuit 110. Specifically, the gate driving circuit 120 outputs the gate signal synchronized with the source signals to the gate line in response to the gate start pulse, gate shift clock, and gate output enable signals by the timing control circuit 110.

The gate driving circuit 120 includes a gate shift register circuit, a gate level shifter circuit, and the like. In this regard, the gate shift register circuit may be formed directly on a TFT array substrate of the display panel 60 using a gate in panel (GIP) process. In this case, the gate driving circuit 120 supplies the gate start pulse and gate shift clock signals to the gate shift register circuit formed via the GIP on the TFT array substrate.

The data driving circuit 130 converts the second image data DATA2 into the source signal in response to the timing signal generated by the timing control circuit 110. Specifically, the data driving circuit 130 converts the second image data DATA2 into the source signal in response to the source start pulse, source sampling clock, and source output enable signals. The data driving circuit 130 outputs one horizontal line of the source signal to the data lines every horizontal period in which the gate signal is supplied to the gate line.

In this regard, the data driving circuit 130 may receive a gamma voltage from a gamma voltage generator (not shown) and convert the second image data DATA2 into the source signal using the gamma voltage. To this end, as shown in FIG. 2, the data driving circuit 130 includes a shift register circuit 210, a latch circuit 220, a level shifter circuit 230, a digital analog converter circuit 240, and an output buffer circuit 250.

The shift register circuit 210 receives the source start pulse and the source sampling clock from the timing control circuit 110, and sequentially shifts the source start pulse based on the source sampling clock to output a sampling signal. The shift register circuit 210 transfers the sampling signal to the latch circuit 220.

The latch circuit 220 sequentially samples and latches the second image data in certain units based on the sampling signal. The latch circuit 220 transfers the latched second image data DATA2 to the level shifter circuit 230.

The level shifter circuit 230 amplifies a level of the latched second image data DATA2. Specifically, the level shifter circuit 230 amplifies the level of the second image data DATA2 to a level at which the digital analog converter circuit 240 may operate. The level shifter circuit 230 transfers the level-amplified second image data DATA2 to the digital analog converter circuit 240.

The digital analog converter circuit 240 converts the second image data DATA2 into the source signal, which is an analog signal. The digital analog converter circuit 240 transfers the source signal, which has been converted to the analog signal, to the output buffer circuit 250.

The output buffer circuit 250 outputs the source signal to the data line DL. Specifically, the output buffer circuit 250 buffers the source signal based on the source output enable signal generated by the timing control circuit 110 and outputs the buffered source signal to the data line.

According to one embodiment of the present disclosure, the shift register circuit 210 and the latch circuit 220 may be driven with the first level voltage, which is the aforementioned low voltage, and the level shifter circuit 230 and the digital analog converter circuit 240 may be driven with the second level voltage. In other words, the shift register circuit 210 and the latch circuit 220 include a low voltage device (LV device) driven with the first level voltage that is the low voltage, and the level shifter circuit 230 and the digital analog converter circuit 240 include a high voltage device (HV device) driven with the second level voltage. That is, the display driver 10 according to one embodiment of the present disclosure may include a semiconductor device including the low voltage device (LV device) and the high voltage device (HV device).

As a geometric size of the low voltage device (LV device) and the high voltage device (HV device) decreases, to prevent a decrease in reliability caused by a decrease in a wire width and an inter-wire pitch of wires connected to each of the low voltage device (LV device) and the high voltage device (HV device), a separate routing layer is required, which may increase a manufacturing cost.

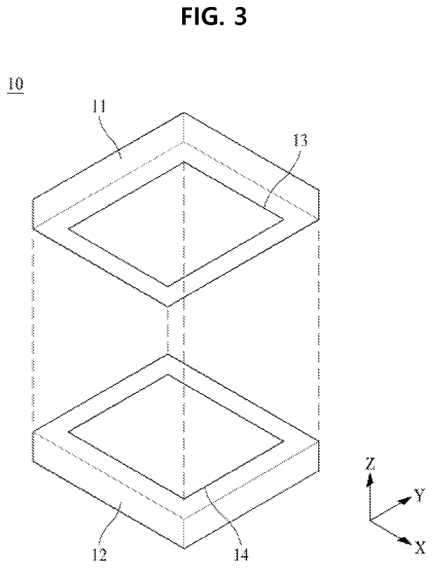

Hereinafter, with reference to FIGS. 3 to 8, a semiconductor device and a display driver including the same according to an embodiment of the present disclosure will be described in detail.

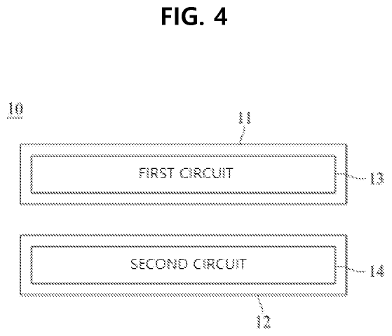

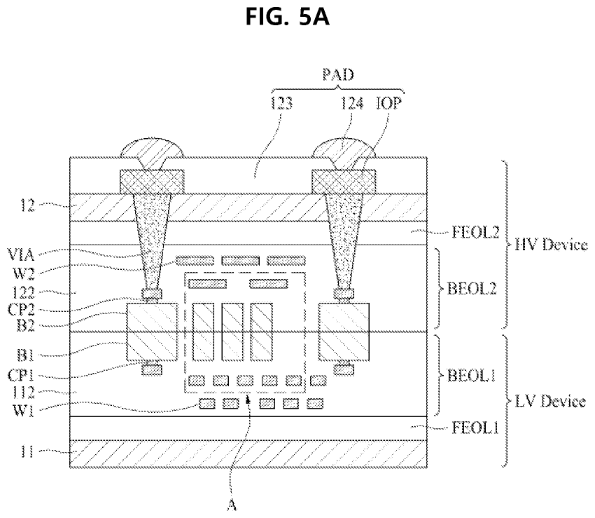

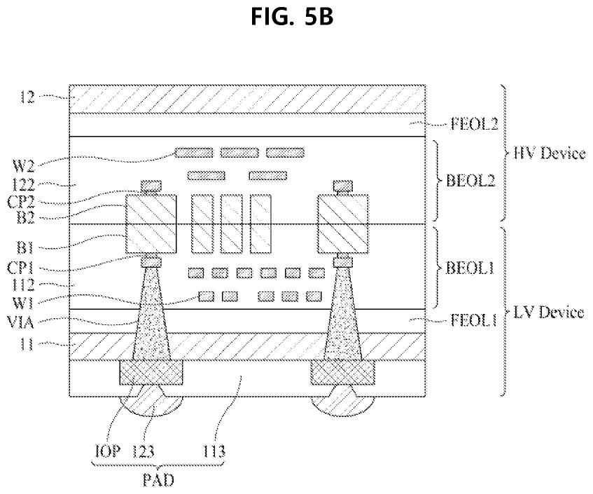

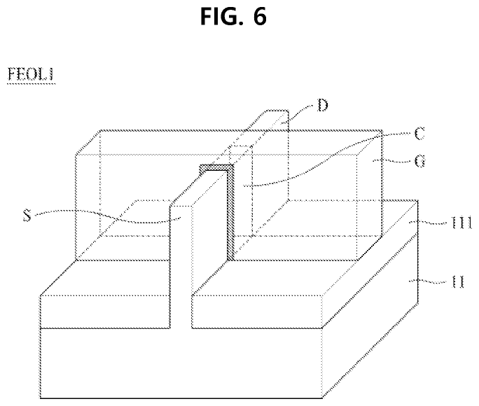

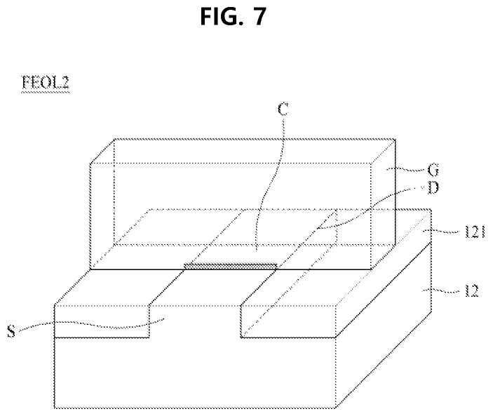

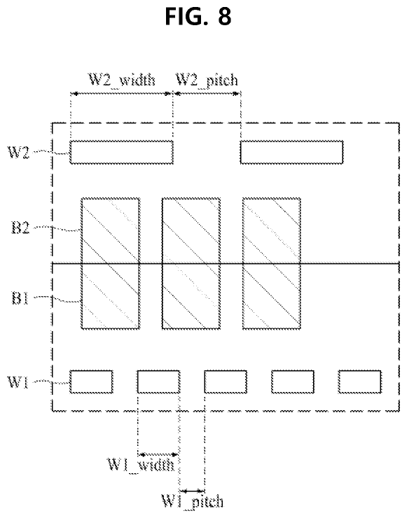

FIG. 3 is a block diagram schematically showing a structure of a display driver according to an embodiment of the present disclosure, and FIG. 4 is a diagram showing first surfaces of first and second substrates on which respective circuits are formed by disassembling a display driver according to an embodiment of the present disclosure. FIG. 5A is a schematic cross-sectional view of a display driver according to an embodiment of the present disclosure, and FIG. 5B is a schematic cross-sectional view of a display driver according to another embodiment of the present disclosure. FIG. 6 is a perspective view of a first FEOL structure of a low voltage device according to an embodiment of the present disclosure, and FIG. 7 is a perspective view of a second FEOL structure of a high voltage device according to an embodiment of the present disclosure. FIG. 8 is an enlarged view of a portion A in FIG. 5A.

Referring to FIGS. 3 and 4, the semiconductor device and the display driver 10 including the same according to one embodiment of the present disclosure include a first substrate 11, a second substrate 12, a first circuit 13, and a second circuit 14.

The first circuit 13 is mounted on the first substrate 11. Specifically, the first circuit 13 may be mounted on a first surface of the first substrate 11. In this regard, according to one embodiment of the present disclosure, the first circuit 13 is driven with the first level voltage, which is the low voltage. That is, the first circuit 13 may include a circuit composed of the low voltage device (LV device) driven with the first level voltage. For example, the first circuit 13 may include the shift register circuit 210 and the latch circuit 220 composed of the low voltage device (LV device) driven with the first level voltage.

The second circuit 14 is mounted on the second substrate 12. Specifically, the second circuit 14 may be mounted on a first surface of the second substrate 12. In this regard, according to one embodiment of the present disclosure, the second circuit 14 is driven with the second level voltage that is the high voltage, which is the voltage higher than the first level voltage that is the low voltage. That is, the second circuit 14 may include a circuit composed of the high voltage device (HV device) driven with the second level voltage. For example, the second circuit 14 may include the level shifter circuit 230 and the digital analog converter circuit 240 composed of the high voltage device (HV device) driven with the second level voltage.

The first substrate 11 and the second substrate 12 may be coupled and bonded to each other. For example, the first substrate 11 and the second substrate 12 may be coupled to each other using a bonding scheme using a bonding metal. In this regard, as described above, the first circuit 13 and the second circuit 14, which are respectively mounted on the first substrate 11 and the second substrate 12, may be mounted on the first surfaces, which are surfaces facing each other when the first substrate 11 and the second substrate 12 are coupled to each other. However, the present disclosure may not be limited thereto, and the display driver 10 may further include a third circuit driven with a voltage other than the first level voltage and the second level voltage, and the third circuit may be mounted on at least one of the first substrate 11 and the second substrate 12.

The semiconductor device and the display driver including the same according to one embodiment of the present disclosure may be manufactured via a wafer-on-wafer process. Compared to manufacturing with one wafer, the present disclosure is manufactured by respectively forming the circuits on a first wafer, which is the first substrate 11, and a second wafer, which is the second substrate 12, and coupling the wafers to each other, so that the number of masks required may be reduced and thus the cost may be reduced.

Referring to FIGS. 5A to 6, the low voltage device (LV device) includes a first front-end-of-line (FEOL) structure FEOL1 and a first back-end-of-line (BEOL) structure BEOL1 formed on the first surface of the first substrate 11.

The first substrate 11 may contain one or more semiconductor materials. For example, the semiconductor materials may be Si, Ge, SiGe, GaP, GaAs, SiC, SiGeC, and/or InP. In some embodiments, the first substrate 11 may be a bulk substrate (e.g., a bulk silicon substrate) or a semiconductor on insulator (SOI) substrate.

The first FEOL structure FEOL1 may be disposed on the first surface of the first substrate 11. The first FEOL structure FEOL1 may be formed via a FEOL process. The FEOL process may refer to a process of forming individual elements, for example, a transistor, a capacitor, and a resistor, on the first substrate 11 during a manufacturing process of the semiconductor device. For example, the FEOL process may include planarizing and cleaning the wafer, forming a trench, forming a well, forming the gate line, forming a source and a drain, and the like.

In particular, according to one embodiment of the present disclosure, the first FEOL structure FEOL1 includes a fin field effect transistor (FinFET), as shown in FIG. 6. Accordingly, because one transistor included in the low voltage device (LV device) of the semiconductor device according to one embodiment of the present disclosure is disposed in a smaller area on a plane than one transistor included in the high voltage device (HV device), a degree of integration of the low voltage device (LV device) may be improved. Additionally, the low voltage device (LV device) according to one embodiment of the present disclosure may have improved voltage characteristics by the FinFET.

As shown in FIG. 6, the first FEOL structure FEOL1 may include a first lower insulating film 111, a channel area C, a source area S, a drain area D, a gate area G, and an insulating capping layer (not shown).

The first lower insulating film 111 may be disposed to have a predetermined thickness on both side surfaces of each of the channel area C, the source area S, and the drain area D on the first surface of the first substrate 11. The first lower insulating film 111 may be disposed only on lower portions of both side surfaces of each of the channel area C, the source area S, and the drain area D. The first lower insulating film 111 may contain an insulating material. For example, the first lower insulating film 111 may contain silicon oxide, silicon nitride, and/or silicon oxynitride.

A protrusion height of the channel area C, the source area S, and the drain area D may be greater than the thickness of the first lower insulating film 111. That is, the channel area C, the source area S, and the drain area D may be in a form of protruding on the first lower insulating film 111 by extending therethrough.

Although not shown, the channel area C may include, for example, a well doped with a dopant or a conductive area doped with the dopant. Specifically, the conductive area may include at least one of a first doped area and a second doped area. In this regard, the first doped area may be an n-type doped area and the second doped area may be a p-type doped area. Additionally, such first doped area may include a first fin-type active area and such second doped area may include a second fin-type active area.

The source area S and the drain area D may be of a fin-type of protruding vertically with the channel area C interposed therebetween and may be separated from each other and disposed on the first lower insulating film 111. In this regard, each of the source area S and the drain area D may be in contact with the channel area C. For example, the source area S may be in contact with one surface of the channel area C and the drain area D may be in contact with a surface opposite to the one surface of the channel area C. The source area S and the drain area D may contain a semiconductor material and/or dopant atoms (e.g., B, P, or As atoms).

The gate area G extends to surround three surfaces of the channel area C on the first lower insulating film 111. In this regard, the gate area G may extend along a direction perpendicular to a direction in which the source area S and the drain area D extend on the plane. However, the extension direction of the gate area G is not limited thereto.

Although not shown, the insulating capping layer may be disposed on the first lower insulating film 111 and cover the channel area C, the source area S, the drain area D, and the gate area G. In this regard, a top surface of the insulating capping layer may be flat. For example, the insulating capping layer may be made of a silicon nitride film.

The first BEOL structure BEOL1 may be disposed on the first FEOL structure FEOL1. The first BEOL structure BEOL1 may be formed by a BEOL process. The BEOL process may refer to a process of interconnecting the individual elements, for example, the transistor, the capacitor, and the resistor, during the manufacturing process of the semiconductor device. For example, the BEOL process may include performing silicidation of the gate area G, the source area S, and the drain area D, adding a dielectric, performing planarization, defining a hole, forming a contact plug, forming a passivation layer, forming a via, and the like.

The first BEOL structure BEOL1 may include a plurality of multilayer wiring structures electrically connected to the first FEOL structure FEOL1, and a first bonding structure B1 coupled to the second substrate 12.

Each of the plurality of multilayer wiring structures may include a plurality of first wiring layers W1, a plurality of first contact plugs CP1 disposed between the plurality of first wiring layers W1 to connect the plurality of first wiring layers W1 to each other, and a first interlayer insulating film 112.

The plurality of first wiring layers W1 are formed by being patterned in a horizontal direction and are electrically connected to the low voltage device (LV device) of the first FEOL structure FEOL1. The first contact plugs CP1 are formed in a vertical direction and electrically connect the plurality of first wiring layers W1 to each other. Each of the plurality of first wiring layers W1 and the plurality of first contact plugs CP1 may include a metal layer and a conductive barrier film (not shown) covering a surface of the metal layer. The metal layer may be made of Cu, W, Ta, Ti, Co, Mn, Al, or a combination thereof, and the conductive barrier film may be made of Ta, Ti, TaN, TiN, AlN, WN, or a combination thereof. The number of layers of the plurality of first wiring layers W1 stacked sequentially along the vertical direction in each of the plurality of multilayer wiring structures may not be particularly limited and may vary.

The first interlayer insulating film 112 may be disposed to cover the first FEOL structure FEOL1 including the low voltage device (LV device) and insulate at least some of the plurality of first wiring layers W1 and the plurality of first contact plugs CP1. To this end, the first interlayer insulating film 112 may be made of a silicon oxide film, a silicon nitride film, a silicon oxynitride film, or a combination thereof. Additionally, an uppermost layer constituting the first interlayer insulating film 112 may be a passivation layer.

According to one embodiment of the present disclosure, one transistor included in the low voltage device (LV device) of the semiconductor device may be disposed in the smaller area on the plane than one transistor included in the high voltage device (HV device) and the plurality of first wiring layers W1 may be formed at the same scale as the process for forming the first FEOL structure FEOL1 including the FinFET, so that the plurality of first wiring layers W1 may have smaller pitch and wire width than those of a plurality of second wiring layers W2 included in a second BEOL structure BEOL2 to be described later. Specifically, as shown in FIG. 8, the first wiring layer W1 of one transistor included in the low voltage device (LV device) may be formed to have the smaller wire width than the second wiring layer W2 of one transistor included in the high voltage device (HV device) (W1_width<W2_width). In addition, the respective first wiring layers W1 of one transistor and another transistor adjacent thereto included in the low voltage device (LV device) may be formed to be spaced apart from each other with a pitch smaller than a pitch between the respective second wiring layers W2 of one transistor and another transistor adjacent thereto included in the high voltage device (HV device) (W1_pitch<W2_pitch).

The first bonding structure B1 may be coupled with a second bonding structure B2 of the second BEOL structure BEOL2, which will be described later, so that the first substrate 11 and the second substrate 12 may be coupled to each other. For example, the first bonding structure B1 may be coupled with the second bonding structure B2 via the bonding scheme using the bonding metal. According to one embodiment of the present disclosure, the first bonding structure B1 may contain a conductive metal and be electrically connected to the multilayer wiring structure of the first BEOL structure BEOL1. For example, the first bonding structure B1 may contain the conductive metal such as Cu or Au. Accordingly, because the low voltage device (LV device) and the high voltage device (HV device) formed on different substrates may be electrically connected to each other via the first bonding structure B1 and the second bonding structure B2, a separate structure for electrically connecting the low voltage device (LV device) with the high voltage device (HV device) may be omitted.

However, the present disclosure may not be limited thereto, and the first bonding structure B1 may be coupled to the second bonding structure B2 using wire bonding using a wire, flip chip bonding achieving connection via a bump, and through silicon via (TSV) bonding schemes. Additionally, the low voltage device (LV device) and the high voltage device (HV device) may be electrically connected to each other via another structure.

Referring to FIGS. 5A and 7, the high voltage device (HV device) may have a second front-end-of-line (FEOL) structure FEOL2 and a second back-end-of-line (BEOL) structure BEOL2 formed on a first surface of the second substrate 12, and an input/output pad IOP.

The second substrate 12 may contain one or more semiconductor materials. For example, the semiconductor material may be Si, Ge, SiGe, GaP, GaAs, SiC, SiGeC, and/or InP. In some embodiments, the second substrate 12 may be a bulk substrate (e.g., a bulk silicon substrate) or a semiconductor on insulator (SOI) substrate.

As described above, the second FEOL structure FEOL2 may be disposed on the first surface of the second substrate 12 facing the first substrate 11. The second FEOL structure FEOL2 may be formed by the FEOL process. The FEOL process may refer to a process of forming individual elements, for example, a transistor, a capacitor, and a resistor, on the second substrate 12 during the manufacturing process of the semiconductor device. For example, the FEOL process may include planarizing and cleaning the wafer, forming the trench, forming the well, forming the gate line, forming the source and the drain, and the like.

The second FEOL structure FEOL2 may include a second lower insulating film 121, the channel area C, the source area S, the drain area D, the gate area G, and the insulating capping layer (not shown).

The second lower insulating film 121 may be disposed to have a predetermined thickness on both side surfaces of each of the channel area C, the source area S, and the drain area D on the first surface of the second substrate 12. The second lower insulating film 121 may contain the insulating material. For example, the second lower insulating film 121 may contain silicon oxide, silicon nitride, and/or silicon oxynitride.

The protrusion height of the channel area C, the source area S, and the drain area D may be substantially equal to the thickness of the second lower insulating film 121. That is, the channel area C, the source area S, and the drain area D may extend through the second lower insulating film 121, and respective top surfaces of the channel area C, the source area S, and the drain area D may have substantially the same height from the first surface of the second substrate 12 as the top surface of the second lower insulating film 121.

Although not shown, the channel area C may include, for example, the well doped with the dopant or the conductive area doped with the dopant. Specifically, the conductive area may include at least one of the first doped area and the second doped area. In this regard, the first doped area may be the n-type doped area and the second doped area may be the p-type doped area. Additionally, such first doped area may include a first active area and such second doped area may include a second active area.

The source area S and the drain area D may be separated from each other with the channel area C interposed therebetween and may be disposed through the second lower insulating film 121. In this regard, each of the source area S and the drain area D may be in contact with the channel area C. For example, the source area S may be in contact with one surface of the channel area C and the drain area D may be in contact with a surface opposite to the one surface of the channel area C. The source area S and the drain area D may contain the semiconductor material and/or the dopant atoms (e.g., the B, P or As atoms).

The gate area G covers a top surface of the channel area C on the second lower insulating film 121. In this regard, the gate area G may extend along the direction perpendicular to the direction in which the source area S and the drain area D extend on the plane. However, the extension direction of the gate area G is not limited thereto.

Although not shown, the insulating capping layer may be disposed on the second lower insulating film 121 and cover the channel area C, the source area S, the drain area D, and the gate area G. In this regard, the top surface of the insulating capping layer may be flat. For example, the insulating capping layer may be made of the silicon nitride film.

Again, although it is shown in FIG. 5A that the second FEOL structure FEOL2 is disposed on the second BEOL structure BEOL2, the second FEOL structure FEOL2 may be disposed on the first surface of the second substrate 12 facing the first surface of the first substrate 11 and the second BEOL structure BEOL2 may be disposed on the second FEOL structure FEOL2 based on the first surface of the second substrate 12. The second BEOL structure BEOL2 may be formed by the BEOL process. The BEOL process may refer to the process of interconnecting the individual elements, for example, the transistor, the capacitor, and the resistor, during the manufacturing process of the semiconductor device. For example, the BEOL process may include performing the silicidation of the gate area G, the source area S, and the drain area D, adding the dielectric, performing the planarization, defining the hole, forming the contact plug, forming the passivation layer, forming the via, and the like.

The second BEOL structure BEOL2 may include a plurality of multilayer wiring structures electrically connected to the second FEOL structure FEOL2, and the second bonding structure B2 coupled to the first substrate 11.

Each of the plurality of multilayer wiring structures may include the plurality of second wiring layers W2, a plurality of second contact plugs CP2 disposed between the plurality of second wiring layers W2 to connect the plurality of second wiring layers W2 to each other, and a second interlayer insulating film 122.

The plurality of second wiring layers W2 may be formed by being patterned in the horizontal direction and may be electrically connected to the high voltage device (HV device) of the second FEOL structure FEOL2. The second contact plug CP2 is formed in the vertical direction and electrically connects the plurality of second wiring layers W2 to each other. Each of the plurality of second wiring layers W2 and the plurality of second contact plugs CP2 may include a metal layer and a conductive barrier film (not shown) covering a surface of the metal layer. The metal layer may be made of Cu, W, Ta, Ti, Co, Mn, Al, or a combination thereof, and the conductive barrier film may be made of Ta, Ti, TaN, TiN, AlN, WN, or a combination thereof. The number of layers of the plurality of second wiring layers W2 stacked sequentially along the vertical direction in each of the plurality of multilayer wiring structures may not be particularly limited and may vary.

According to one embodiment of the present disclosure, each of the plurality of multilayer wiring structures may further include a via VIA that electrically connects a pad structure PAD, which will be described later, with the first and second bonding structures B1 and B2. The via VIA may electrically connect the first and second bonding structures B1 and B2 or the second wiring layer W2 and the pad structure PAD to each other. Specifically, one end of the VIA may be electrically connected to the second bonding structure B2 by being in contact with the second contact plug CP2 or the second wiring layer W2, which is electrically connected to the second bonding structure B2, or may be electrically connected to the second bonding structure B2 by being in direct contact with the second bonding structure B2. The other end of the via VIA may be electrically connected to the pad structure PAD, which will be described later, by being in direct contact with the pad structure PAD. Accordingly, a signal input to the pad structure PAD may be transferred to the first FEOL structure FEOL1 and first BEOL structure BEOL1 or to the second FEOL structure FEOL2 and the second BEOL structure BEOL2 via the via VIA and the first and second bonding structures B1 and B2. To this end, as shown in FIG. 5A, the via VIA may extend through the second FEOL structure FEOL2 and the second substrate 12 and be in direct contact with and electrically connected to the pad structure PAD. However, although it has been described that the pad structure PAD is located on a second surface of the second substrate 12 and the via VIA is included in the plurality of multilayer wiring structures of the second BEOL structure BEOL2, but the present disclosure is not limited thereto. According to another embodiment of the present disclosure, as shown in FIG. 5B, the via VIA may be included in the plurality of multilayer wiring structures of the first BEOL structure BEOL1, depending on a location of the pad structure PAD. That is, when the pad structure PAD is located on a second surface of the first substrate 11 and the via VIA is included in the plurality of multilayer wiring structures of the first BEOL structure BEOL1, the via VIA may electrically connect the first and second bonding structures B1 and B2 or the first wiring layer W1 and the pad structure PAD to each other. Specifically, one end of the via VIA may be electrically connected to the first bonding structure B1 by being in contact with the first contact plug CP1 or the first wiring layer W1, which is electrically connected to the first bonding structure B1, or may be electrically connected to the first bonding structure B1 by being in direction contact with the first bonding structure B1. The other end of the via VIA may be electrically connected to the pad structure PAD, which will be described later, by being in direct contact with the pad structure PAD. Accordingly, the signal input to the pad structure PAD may be transferred to the first FEOL structure FEOL1 and the first BEOL structure BEOL1 or to the second FEOL structure FEOL2 and the second BEOL structure BEOL2 via the via VIA and the first and second bonding structures B1 and B2. To this end, the via VIA may extend through the second FEOL structure FEOL2 and the second substrate 12 and may be in direct contact with and electrically connected to the pad structure PAD as shown in FIG. 5A, or the input/output pad IOP may be located in the low voltage device (LV device) and the via VIA may extend through the first FEOL structure FEOL1 and the first substrate 11 and may be in direct contact with and electrically connected to the pad structure PAD as shown in FIG. 5B.

The second interlayer insulating film 122 may be disposed to cover the second FEOL structure FEOL2 including the high voltage device (HV device), and insulate some of the plurality of second wiring layers W2 and the plurality of second contact plugs CP2. To this end, the second interlayer insulating film 122 may be made of a silicon oxide film, a silicon nitride film, a silicon oxynitride film, or a combination thereof. Additionally, an uppermost layer constituting the second interlayer insulating film 122 may be a passivation layer.

According to one embodiment of the present disclosure, one transistor included in the high voltage device (HV device) of the semiconductor device may be disposed in a larger area on the plane than one transistor included in the low voltage device (LV device) and the plurality of second wiring layers W2 may be formed at the same scale as the process for forming the second FEOL structure FEOL2 including the planar FET, so that the plurality of second wiring layers W2 may have greater pitch and wire width than those of the plurality of first wiring layers W1 included in the first BEOL structure BEOL1. Specifically, as shown in FIG. 8, the second wiring layer W2 of one transistor included in the high voltage device (HV device) may be formed to have the greater wire width than the first wiring layer W1 of one transistor included in the low voltage device (LV device) (W2_width>W1_width). In addition, the respective second wiring layers W2 of one transistor and another transistor adjacent thereto included in the high voltage device (HV device) may be formed to be spaced apart from each other with a pitch greater than a pitch between the respective first wiring layers W1 of one transistor and another transistor adjacent thereto included in the low voltage device (LV device) (W2_pitch>W1_picth).

Accordingly, not only the semiconductor device according to one embodiment of the present disclosure may prevent a decrease in reliability of the plurality of second wiring layers W2 of the high voltage device (HV device) having the second BEOL structure BEOL2, but also the high voltage device (HV device) having the second FEOL structure FEOL2 including the planar FET and the second BEOL structure BEOL2 may be manufactured with a lower manufacturing cost compared to the high voltage device having the first FEOL structure FEOL1 including the FinFET and the first BEOL structure BEOL1.

The second bonding structure B2 may be coupled with the first bonding structure B1 of the first BEOL structure BEOL1 to couple the first substrate 11 with the second substrate 12. For example, the second bonding structure B2 may be coupled with the second bonding structure B2 via the bonding scheme using the bonding metal. According to one embodiment of the present disclosure, the second bonding structure B2 may contain a conductive metal and be electrically connected to the multilayer wiring structure of the first BEOL structure BEOL1. For example, the second bonding structure B2 may contain the conductive metal such as Cu or Au. Accordingly, because the low voltage device (LV device) and the high voltage device (HV device) formed on the different substrates may be electrically connected to each other via the first bonding structure B1 and the second bonding structure B2, the separate structure for electrically connecting the low voltage device (LV device) with the high voltage device (HV device) may be omitted.

However, the present disclosure may not be limited thereto, and the second bonding structure B2 may be coupled to the first bonding structure B1 using the wire bonding using the wire, the flip chip bonding achieving the connection via the bump, and the through silicon via (TSV) bonding schemes. Additionally, the low voltage device (LV device) and the high voltage device (HV device) may be electrically connected to each other via another structure.

Additionally, referring again to FIGS. 5A and 5B, the semiconductor device according to one embodiment of the present disclosure includes the pad structure PAD that receives a signal from the outside or outputs a signal to the outside. The pad structure PAD may include the input/output pad IOP, pad insulating films 113 and 123, and solder balls 114 and 124.

The input/output pad IOP may be located on the second surface of the second substrate 12, which does not face the first substrate 11, and may be electrically connected to the via VIA by being in direct contact therewith to perform input or output of the signal with the first wiring layer W1 or the second wiring layer W2 that is electrically connected to the via VIA.

The pad insulating films 113 and 123 are disposed to cover a portion of the input/output pad IOP and insulate a portion of the input/output pad IOP. To this end, the pad insulating films 113 and 123 may be made of a silicon oxide film, a silicon nitride film, a silicon oxynitride film, or a combination thereof.

The solder balls 114 and 124 are disposed to be in direct contact with the input/output pad IOP in areas where the input/output pad IOP is exposed as the pad insulating films 113 and 123 are not disposed. Accordingly, the solder balls 114 and 124 may transfer the signal input from the outside to the high voltage device (HV device) or the low voltage device (LV device) or output the signal transferred from the high voltage device (HV device) or the low voltage device (LV device) to the outside. To this end, the solder balls 114 and 124 may be made of Au, C4 (Controlled-Collapse Chip Connection), Cu, or the like.

Those skilled in the art of the technical field to which the present disclosure belongs will understand that the above-described present disclosure may be implemented in other specific forms without changing a technical idea or essential features thereof.

Additionally, the methods described herein may be at least partially implemented using one or more computer programs or components. Such components may be provided as a series of computer instructions via a computer-readable medium or machine-readable medium including volatile and non-volatile memory. The instructions may be provided as software or firmware, and may be entirely or partially implemented in hardware components such as ASICs, FPGAs, DSPs, or other similar elements. The instructions may be executed by one or more processors or other hardware components, which, when executing the series of computer instructions, performs or is able to perform all or some of the methods and the procedures disclosed herein.

Therefore, the embodiments described above should be understood in all respects as illustrative and not restrictive. The scope of the present disclosure is indicated by the patent claims to be described later rather than the detailed description above, and it should be interpreted that the meaning and scope of the patent claims and all changes or modified forms derived from the equivalent concept are included in the scope of the present disclosure.

What is claimed is:

1. A semiconductor device comprising:
a low voltage device located on a first substrate and driven with a first level voltage; and
a high voltage device located on a second substrate, driven with a second level voltage higher than the first level voltage, and coupled to the low voltage device,
wherein the low voltage device includes a FinFET,
wherein the high voltage device includes a planar FET.

2. The semiconductor device of claim 1, wherein the low voltage device includes a plurality of first wiring layers and a first interlayer insulating film insulating some of the plurality of first wiring layers,
wherein the high voltage device includes a plurality of second wiring layers and a second interlayer insulating film insulating some of the plurality of second wiring layers,
wherein the plurality of first wiring layers have a pitch defined therebetween smaller than a pitch defined between the plurality of second wiring layers on a plane.

3. The semiconductor device of claim 1, wherein the low voltage device includes a plurality of first wiring layers,
wherein the high voltage device includes a plurality of second wiring layers,
wherein the plurality of first wiring layers have a wire width smaller than a wire width of the plurality of second wiring layers on a plane.

4. The semiconductor device of claim 1, wherein the low voltage device is located on a first surface of the first substrate,
wherein the high voltage device is located on a first surface of the second substrate facing the first surface of the first substrate,
wherein the first surface of the first substrate and the first surface of the second substrate are coupled to and bonded to each other.

5. The semiconductor device of claim 4, wherein the low voltage device includes a first bonding structure,
wherein the high voltage device includes a second bonding structure coupled with the first bonding structure as the first surface of the first substrate and the first surface of the second substrate face each other.

6. The semiconductor device of claim 5, wherein the low voltage device and the high voltage device are electrically connected to each other by the first bonding structure and the second bonding structure.

7. The semiconductor device of claim 5, wherein the first bonding structure and the second bonding structure contain a conductive metal.

8. The semiconductor device of claim 1, wherein the low voltage device is located on a first surface of the first substrate,
wherein the high voltage device is located on a first surface of the second substrate facing the first surface of the first substrate,
wherein the low voltage device includes a first bonding structure,
wherein the high voltage device includes a second bonding structure facing and coupled to the first bonding structure,
wherein the semiconductor device further includes a pad structure located on a second surface of the first substrate opposite to the first surface of the first substrate or on a second surface of the second substrate opposite to the first surface of the second substrate,
wherein at least some of the first and second bonding structures are electrically connected to the pad structure.

9. The semiconductor device of claim 1, wherein the low voltage device is located on a first surface of the first substrate,
wherein the high voltage device is located on a first surface of the second substrate facing the first surface of the first substrate,
wherein the low voltage device includes a first FEOL structure including the FinFET and a first BEOL structure including a plurality of first wiring layers,
wherein the high voltage device includes a second FEOL structure including the planar FET and a second BEOL structure including a plurality of second wiring layers,
wherein the semiconductor device further includes a pad structure located on a second surface of the first substrate opposite to the first surface of the first substrate,
wherein the low voltage device includes a via extending through the first substrate and the first FEOL structure and electrically connecting the pad structure and the low voltage device or the second BEOL structure to each other.

10. The semiconductor device of claim 1, wherein the low voltage device is located on a first surface of the first substrate,
wherein the high voltage device is located on a first surface of the second substrate facing the first surface of the first substrate,
wherein the low voltage device includes a first FEOL structure including the FinFET and a first BEOL structure including a plurality of first wiring layers,
wherein the high voltage device includes a second FEOL structure including the planar FET and a second BEOL structure including a plurality of second wiring layers,
wherein the semiconductor device further includes a pad structure located on a second surface of the second substrate opposite to the first surface of the second substrate,
wherein the high voltage device includes a via extending through the second substrate and the second FEOL structure and electrically connecting the pad structure and the first FEOL structure or the second FEOL structure to each other.

11. The semiconductor device of claim 1, further comprising a pad structure electrically connected to the low voltage device and the high voltage device, wherein the pad structure includes:
an input/output pad electrically connected to at least one of the low voltage device and the high voltage device;
a pad insulating film covering a portion of the input/output pad and exposing at least a portion of the input/output pad; and
a solder ball electrically connected to the input/output pad by being in direct contact with the input/output pad in an area where the input/output pad is exposed.

12. A display driver including a semiconductor device, the display driver comprising:
a first circuit driven with a first level voltage; and
a second circuit driven with a second level voltage higher than the first level voltage, wherein the second circuit faces the first circuit and is coupled to and bonded to the first circuit,
wherein the first circuit includes a low voltage device including a FinFET,
wherein the second circuit includes a high voltage device including a planar FET.

13. The display driver of claim 12, wherein the low voltage device includes a plurality of first wiring layers and a first interlayer insulating film insulating some of the plurality of first wiring layers,
wherein the high voltage device includes a plurality of second wiring layers and a second interlayer insulating film insulating some of the plurality of second wiring layers,
wherein the plurality of first wiring layers have a pitch defined therebetween smaller than a pitch defined between the plurality of second wiring layers.

14. The display driver of claim 12, wherein the low voltage device includes a plurality of first wiring layers,
wherein the high voltage device includes a plurality of second wiring layers,
wherein the plurality of first wiring layers have a wire width smaller than a wire width of the plurality of second wiring layers.

15. The display driver of claim 12, wherein the shift register circuit and the latch circuit include the low voltage device,
wherein the level shifter circuit and the digital analog converter circuit include the high voltage device.

16. The display driver of claim 12, wherein the low voltage device includes a first bonding structure,
wherein the high voltage device includes a second bonding structure coupled with the first bonding structure as a first surface of the first substrate and a first surface of the second substrate face each other,
wherein the low voltage device and the high voltage device are electrically connected to each other by the first bonding structure and the second bonding structure.

17. The display driver of claim 15, wherein the first bonding structure and the second bonding structure contain a conductive metal.

18. The display driver of claim 12, wherein the low voltage device is located on a first surface of the first substrate,
wherein the high voltage device is located on a first surface of the second substrate facing the first surface of the first substrate,
wherein the low voltage device includes a first bonding structure,
wherein the high voltage device includes a second bonding structure facing and coupled to the first bonding structure,
wherein the display driver further includes a pad structure located on a second surface of the first substrate opposite to the first surface of the first substrate or on a second surface of the second substrate opposite to the first surface of the second substrate,
wherein at least some of the first and second bonding structures are electrically connected to the pad structure.

19. The display driver of claim 12, wherein the low voltage device is located on a first surface of the first substrate,
wherein the high voltage device is located on a first surface of the second substrate facing the first surface of the first substrate,
wherein the low voltage device includes a first FEOL structure including the FinFET and a first BEOL structure including a plurality of first wiring layers,
wherein the high voltage device includes a second FEOL structure including the planar FET and a second BEOL structure including a plurality of second wiring layers,
wherein the display driver further includes a pad structure located on a second surface of the first substrate opposite to the first surface of the first substrate,
wherein the low voltage device includes a via extending through the first substrate and the first FEOL structure and electrically connecting the pad structure and the low voltage device or the second BEOL structure to each other.

20. The display driver of claim 12, wherein the low voltage device is located on a first surface of the first substrate,
wherein the high voltage device is located on a first surface of the second substrate facing the first surface of the first substrate,
wherein the low voltage device includes a first FEOL structure including the FinFET and a first BEOL structure including a plurality of first wiring layers,
wherein the high voltage device includes a second FEOL structure including the planar FET and a second BEOL structure including a plurality of second wiring layers,
wherein the display driver further includes a pad structure located on a second surface of the second substrate opposite to the first surface of the second substrate,
wherein the high voltage device includes a via extending through the second substrate and the second FEOL structure and electrically connecting the pad structure and the first FEOL structure or the second FEOL structure to each other.
